(19) United States
(12) Patent Application Publication
(10) Pub. No.: US 2017/0032958 A1
(43) Pub. Date: Feb. 2, 2017

(54) Method for Cleaning Hermetic Semiconductor Packages

(71) Applicant: Infineon Technologies Americas Corp., El Segundo, CA (US)

(72) Inventor: Derek Richardson, Hubbardston, MA (US)

(21) Appl. No.: 15/158,412

(22) Filed: May 18, 2016

Related U.S. Application Data
(60) Provisional application No. 62/198,085, filed on Jul. 28, 2015.

(51) Int. Cl. H01L 21/02; H01L 21/48; B24C 11/00; B08B 9/00; B08B 5/02; B24C 1/00; H01L 21/56; B08B 15/02

(52) U.S. Cl. CPC H01L 21/02057; H01L 21/02082; H01L 21/56; H01L 21/4817; B08B 15/02; B08B 9/00; B08B 5/02; B24C 1/003; B24C 11/00

(57) ABSTRACT

A method for removing undesirable particles from a semiconductor package is disclosed. The method comprises dispensing dry ice into random cavities of the semiconductor package, and removing the undesirable particles from the random cavities using the dry ice, where the dry ice causes the undesirable particles to dislodge from the random cavities, and where the undesirable particles are removed through an exhaust system. The method further comprises placing the semiconductor package into a vacuum, dispensing nitrogen into the random cavities, and hermetically sealing the semiconductor package so as to produce a hermetic semiconductor package. At least one of the random cavities is on a surface of a semiconductor die in the semiconductor package.

### BACKGROUND

The present application claims the benefit of and priority to a provisional patent application entitled “Dry Ice Cleaning in Hermetic Packages” Ser. No. 62/198,085 filed on Jul. 28, 2015. The disclosure in this provisional application is hereby incorporated fully by reference into the present application.

Semiconductor power modules control electrical power to circuits and devices, such as motors, actuators, controllers or the like. When high reliability is required for use in extreme or harsh environments, such as in high performance vehicles, aircrafts, space shuttles and satellites, it is important to provide hermetic semiconductor packages that are free of undesirable particles, such as contaminants or foreign object debris (FOD). The undesirable particles may be introduced, for example, during the fabrication process of a semiconductor package, but not effectively removed before the semiconductor package is hermetically sealed. These undesirable particles can cause electrical shorts when the hermetic semiconductor package is subjected to vibration and/or high temperature.

Special precautions have been taken to remove undesirable particles, but none has been effective. For example, one conventional technique to clean a semiconductor package is to apply compressed nitrogen spray to remove particles from the semiconductor package. While this technique can remove large particles (e.g., with diameters of greater than 500 microns), it is ineffective when removing small particles (e.g., with diameters of less than or equal to 25 microns), as the compressed nitrogen air creates a high pressure boundary layer over uneven surfaces in the semiconductor package and pushes down the small particles to the bottom of random cavities created by the uneven surfaces. In another conventional technique, one or more liquid cleaning agents are applied to a semiconductor package. However, these liquid cleaning agents are costly and can potentially leave more contaminants behind in the semiconductor package than before they are applied.

Accordingly, there is a need to overcome the drawbacks and deficiencies in the art by providing an effective cleaning method for removing undesirable particles from hermetic semiconductor packages.

### SUMMARY

The present disclosure is directed to a method for cleaning hermetic semiconductor packages, substantially as shown in and/or described in connection with at least one of the figures, and as set forth in the claims.

### BRIEF DESCRIPTION OF THE DRAWINGS

FIG. 1 is a flowchart illustrating a method for cleaning a hermetic semiconductor package according to one implementation of the present application.

FIG. 2 illustrates exemplary structures in accordance with an initial action in the flowchart of FIG. 1 according to one implementation of the present application.

FIG. 3A illustrates exemplary structures in accordance with an intermediate action in the flowchart of FIG. 1 according to one implementation of the present application.

FIG. 3B illustrates an enlarged view of a portion of a semiconductor package processed in accordance with an intermediate action in the flowchart of FIG. 1 according to one implementation of the present application.

FIG. 3C illustrates an enlarged view of a portion of a semiconductor package processed in accordance with one or more intermediate actions in the flowchart of FIG. 1 according to one implementation of the present application.

FIG. 4A illustrates exemplary structures in accordance with an intermediate action in the flowchart of FIG. 1 according to one implementation of the present application.

FIG. 4B illustrates an enlarged view of a portion of a semiconductor package processed in accordance with an intermediate action in the flowchart of FIG. 1 according to one implementation of the present application.

FIG. 4C illustrates an enlarged view of a portion of a semiconductor package processed in accordance with one or more intermediate actions in the flowchart of FIG. 1 according to one implementation of the present application.

FIG. 5 illustrates exemplary structures in accordance with a final action in the flowchart of FIG. 1 according to one implementation of the present application.

### DETAILED DESCRIPTION

The following description contains specific information pertaining to implementations in the present disclosure. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions.

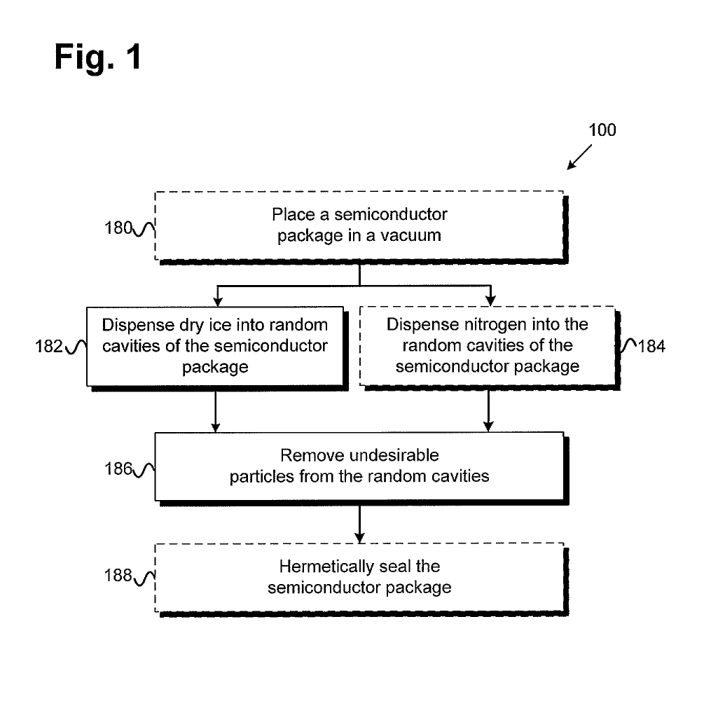

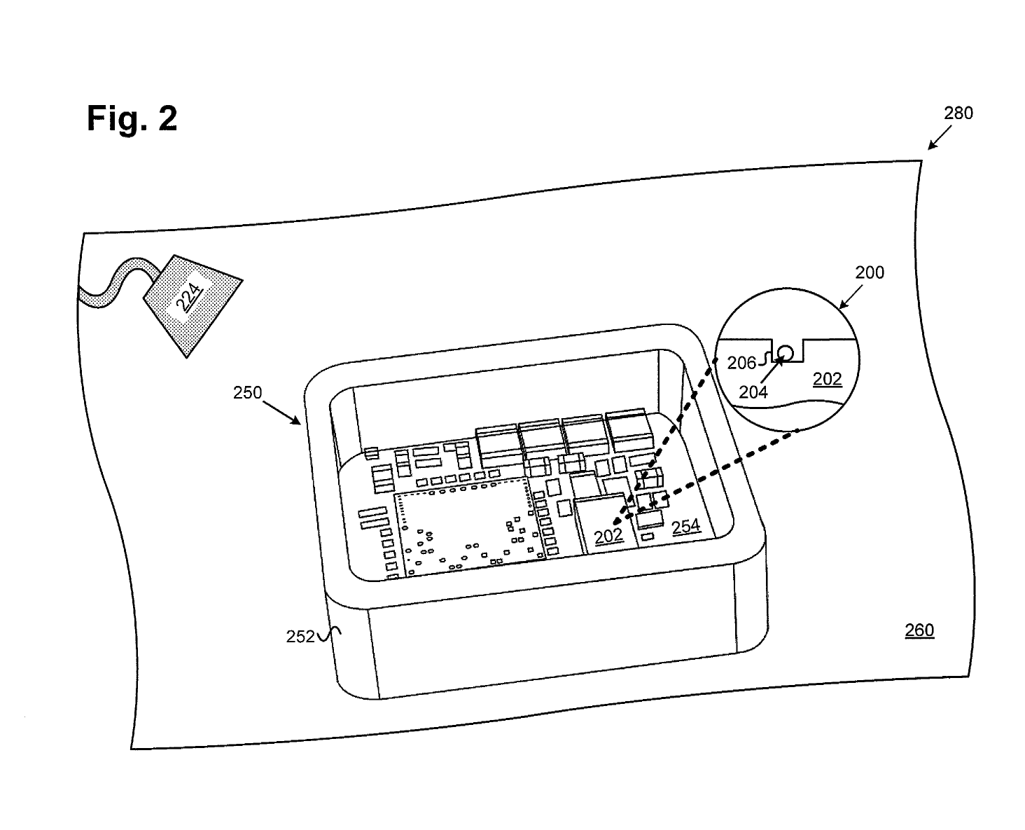

FIG. 1 shows a flowchart illustrating an exemplary method for cleaning a hermetic semiconductor package according to an implementation of the present application. Certain details and features have been left out of the flowchart that are apparent to a person of ordinary skill in the art. For example, an action may consist of one or more subactions or may involve specialized equipment or materials, as known in the art. Actions 180, 182, 184, 186 and 188 indicated in flowchart 100 are sufficient to describe one implementation of the present inventive concepts, other implementations of the present inventive concepts may utilize actions different from those shown in flowchart 100. Moreover, structures 280, 382, 300C, 486 and 588 in FIGS. 2, 3A, 3C, 4A and 5 illustrate the results of performing actions 180, 182, 184, 186 and 188 of flowchart 100, respectively. For example, structure 280 is an exemplary structure after processing action 180, structure 382 is an exemplary structure after the processing of action 182, structure 300C is an exemplary structure after the processing of action 184, and so forth.

Referring to action 180 in FIG. 1 and structure 280 in FIG. 2, action 180 includes placing a semiconductor package in a vacuum. Referring to FIG. 2, structure 280 illustrates a schematic view of exemplary structures in accordance with action 180 in flowchart 100 of FIG. 1, according to one implementation of the present application. As illustrated in FIG. 2, structure 280 includes semiconductor package 250 in vacuum 260, and exhaust system 224 connected to vacuum 260.

As illustrated in FIG. 2, semiconductor package 250 includes case 252, and substrate 254 disposed in case 252. Case 252 includes sidewalls and a bottom (not explicitly shown in FIG. 2). Substrate 254 is situated in case 252. As illustrated in FIG. 2, semiconductor die 202 and various other circuit components, such as resistors, inductors, capacitor stacks, and tantalum capacitors, are formed on a top side of substrate 254. Substrate 254 also includes a bottom side (not explicitly shown in FIG. 2), where semiconductor devices and/or circuit components may be formed thereon. In another implementation, semiconductor package 250 may include a single semiconductor die situated therein. In one implementation, semiconductor die 202 may include group IV semiconductor material, such as silicon, or group III-V semiconductor material, such as gallium nitride (GaN). In one implementation, semiconductor die 202 may include at least one a semiconductor switch, such as a power metal-oxide-semiconductor field effect transistor (MOSFET), an insulated gate bipolar transistor (IGBT), a high electron mobility transistor (HEMT) (e.g., a gallium nitride or silicon carbide HEMT) or a diode.

In the present implementation, vacuum 260 may be a processing chamber configured to establish a specific vacuum level. In another implementation, vacuum 260 may be any suitable vacuum environment known in the art. Exhaust system 224 is connected to vacuum 260. Exhaust system 224 is configured to remove undesirable particles, such as contaminants or foreign object debris (FOD), and/or reduce the pressure within vacuum 260. In one implementation, semiconductor package 250 may be placed into vacuum 260 through a conveyor belt (not explicitly shown in FIG. 2). It should be noted that, in one implementation, vacuum 260 and exhaust system 224 may be optional, such that semiconductor package 250 can be cleaned in ambient conditions.

As shown in magnified view 200 of FIG. 2, undesirable particle 204 is situated in random cavity 206 of semiconductor die 202. In one implementation, undesirable particle 204 may include non-conductive material, such as silicon. In another implementation, undesirable particle 204 may include conductive material, such as metal or metal alloys. In one implementation, undesirable particle 204 may have a diameter approximately equal to or less than 25 microns (i.e., 10̂−6 meters). In another implementation, undesirable particle 204 may have a diameter greater than 25 microns. In one implementation, random cavity 206 may be a random and undesirable indentation or uneven surface on semiconductor die 202. In the present implementation, random cavity 206 is situated in the topmost layer (e.g., a passivation layer) of semiconductor die 202. It should be understood that although only one random cavity 206 and only one undesirable particle 204 are shown in FIG. 2, there can be more than one random cavities and undesirable particles in semiconductor package 250.

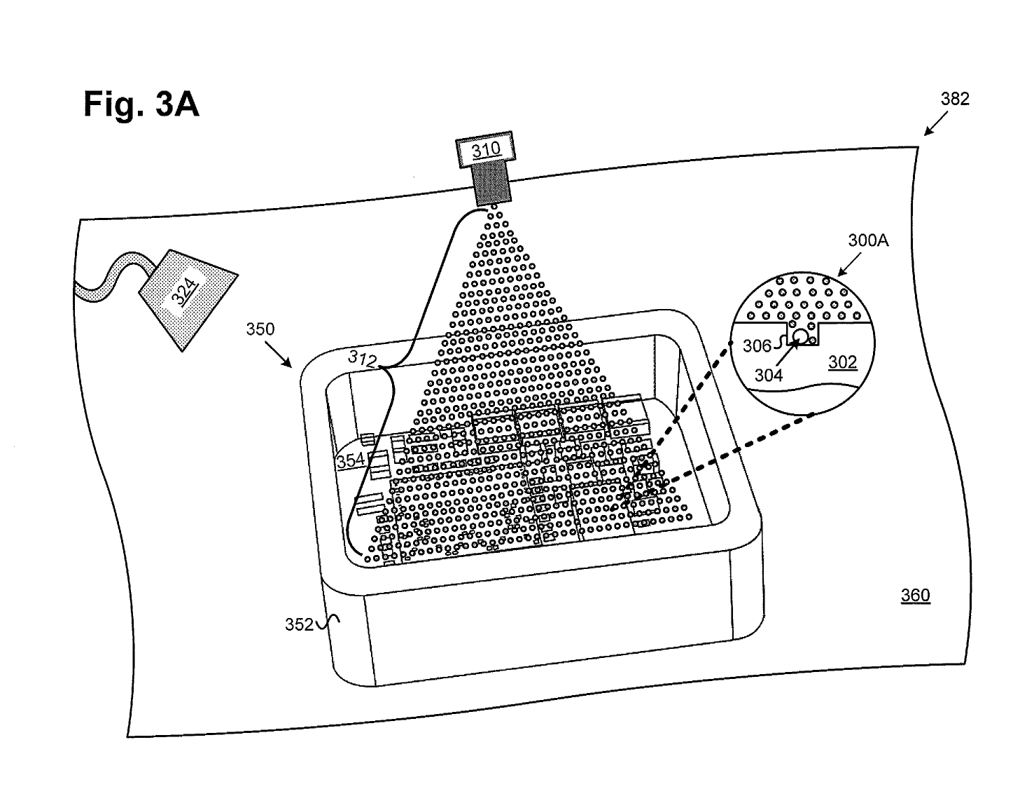

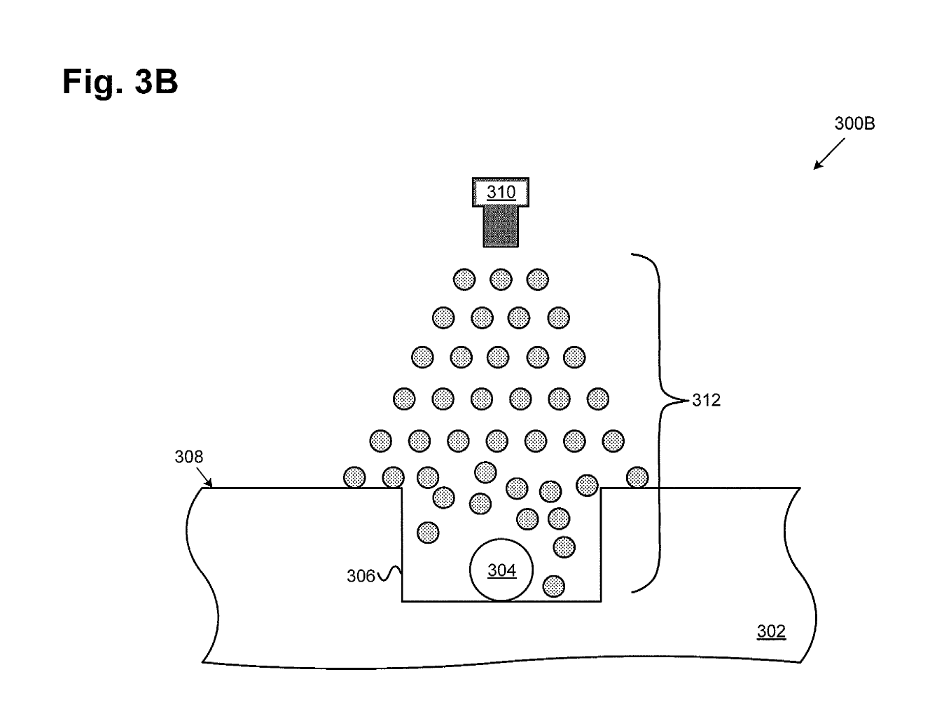

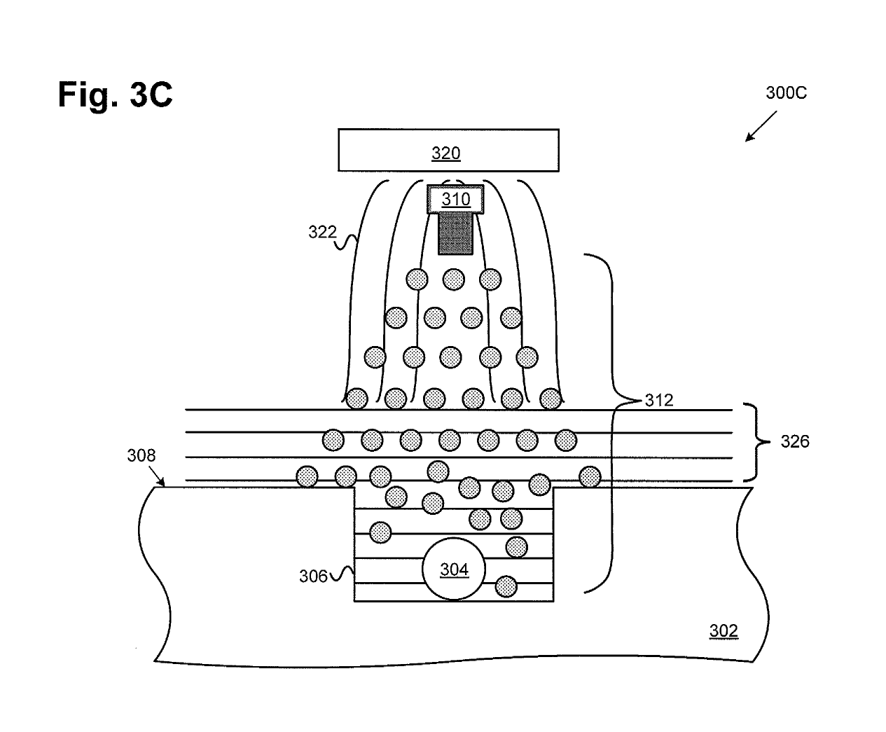

Referring to action 182 in FIG. 1 and structure 382 in FIG. 3A, action 182 includes dispensing dry ice into the random cavities of the semiconductor package. Referring to FIG. 3A, structure 382 illustrates a schematic view of exemplary structures in accordance with action 182 in flowchart 100 of FIG. 1, according to one implementation of the present application. As illustrated in FIG. 3A, with similar numerals representing similar features in FIG. 2, structure 382 includes semiconductor package 350 in vacuum 360, and exhaust system 324 connected to vacuum 360. As illustrated in FIG. 3A, structure 382 also includes dry ice dispenser 310 dispensing dry ice 312 into random cavity 306 of semiconductor package 350.

In one implementation, dry ice 312 may include snow (preferably carbon dioxide snow), dry snow, carbon dioxide (CO₂) and/or a two-phase carbon dioxide mixture which includes carbon dioxide gas and carbon dioxide particles. In another implementation, dry ice 312 may include any grain sizes in a solid aggregate state and/or in the form of individual particles. In another implementation, dry ice 312 may be admixed to a pressurized carrier gas.

In the present implementation, dry ice dispenser 310 is configured to apply, spray and/or blast dry ice to the interior space of semiconductor package 350. For example, dry ice dispenser 310 is configured to dispense dry ice 312 in a pressurized air stream and at a high speed at substrate 354 having all semiconductor devices and circuit components thereon. It should be understood that, although only one dry ice dispenser 310 is shown in FIG. 3A, there can be more than one dry ice dispensers in structure 382 to dispense dry ice 312. During operation, dry ice dispenser 310 can be either stationary or in motion (e.g., tilt, rotate, move transversely and/or rectilinearly translationally) relative to semiconductor package 350.

As shown in magnified view 300A of FIG. 3A, undesirable particle 304 is situated in random cavity 306 of semiconductor die 302 within case 352 of semiconductor package 350. Particles in dry ice 312 are introduced into random cavity 306. Dry ice 312 sublimates into gas substantially upon impact, transferring kinetic energy to undesirable particle 304 and leaving no residue in semiconductor package 350.

Referring to structure 300B in FIG. 3B, structure 300B illustrates magnified view 300A in structure 382 in FIG. 3A. As illustrated in FIG. 3B, undesirable particle 304 is situated in random cavity 306 on top surface 308 of semiconductor die 302 in semiconductor package 350. Dry ice 312 from dry ice dispenser 310 is introduced into random cavity 306 and on top surface 308 of semiconductor die 302. Outside of random cavity 306, dry ice 312 sublimates into gas substantially upon impact, transferring minimal kinetic energy and producing minimal abrasion to top surface 308, and leaving no residue. In random cavity 306, particles in dry ice 312 are smaller than undesirable particle 304, and can enter the interior space of random cavity 306. Dry ice 312 sublimates into gas substantially upon impact, transferring kinetic energy to undesirable particle 304, producing minimal abrasion to random cavity 306, and leaving no residue in random cavity 306.

Referring to actions 182 and 184 in FIG. 1 and structure 300C in FIG. 3C, actions 182 and 184 include dispensing dry ice and nitrogen, respectively, into the random cavities of the semiconductor package. Referring to FIG. 3C, structure 300C illustrates a schematic view of exemplary structures in accordance with actions 182 and 184 in flowchart 100 of FIG. 1, according to one implementation of the present application. As illustrated in FIG. 3C, with similar numerals representing similar features in FIG. 3B, structure 300C includes dry ice dispenser 310 dispensing dry ice 312 into random cavity 306 on semiconductor die 302. Structure 300C also includes nitrogen dispenser 320 dispensing compressed nitrogen 322 into random cavity 306 on semiconductor die 302. Nitrogen dispenser 320 delivers compressed nitrogen 322 to top surface 308 of semiconductor die 302 and the interior space of random cavity 306. While compressed nitrogen 322 can remove large particles (e.g., with diameters of 500 microns or greater) from semiconductor die 302, compressed nitrogen 322 creates high pressure boundary layer 326 over top surface 308, which in absence of dry ice 312 would press undesirable particle 304 (e.g., with a diameter of 25 microns or less) to the bottom of random cavity 306. However, the introduction of dry ice 312 in addition to compressed nitrogen 322 can provide mechanical means for removing undesirable particle 304 from random cavity 306.

In the present implementation, dry ice 312 and compressed nitrogen 322 are dispensed concurrently into random cavity 306 of semiconductor package 350. It should be noted that, in one implementation, nitrogen dispenser 320 dispensing compressed nitrogen 322 to semiconductor package 350 may be optional, such that semiconductor package 350 can be cleaned with only dry ice 312.

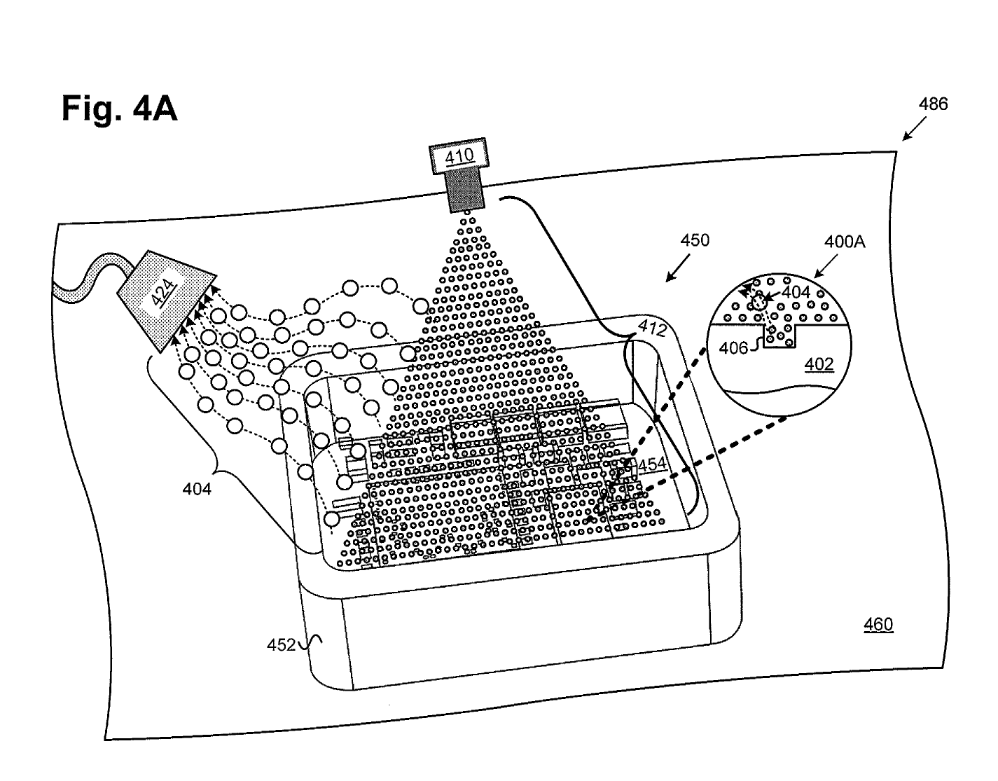

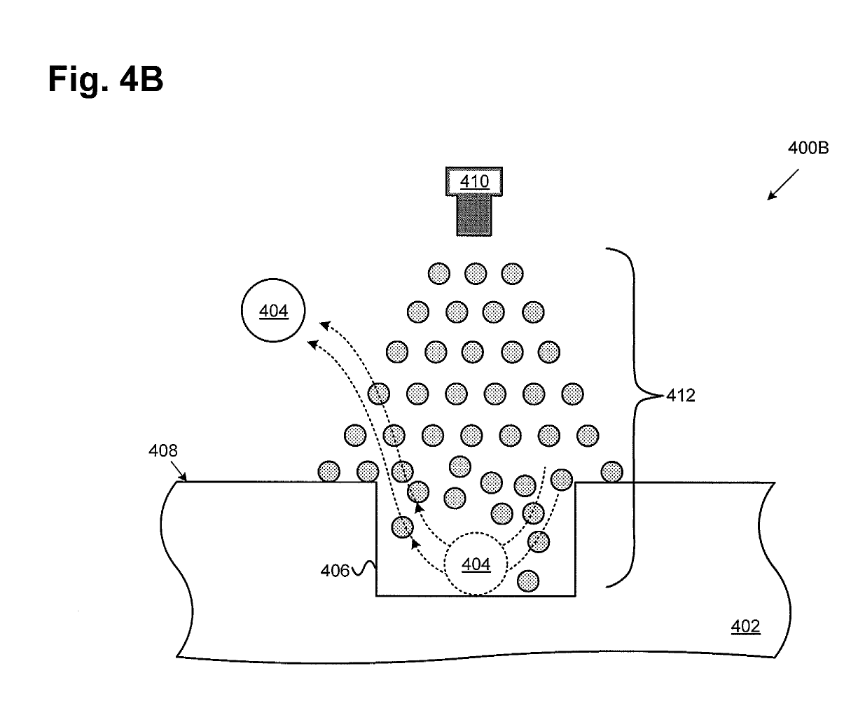

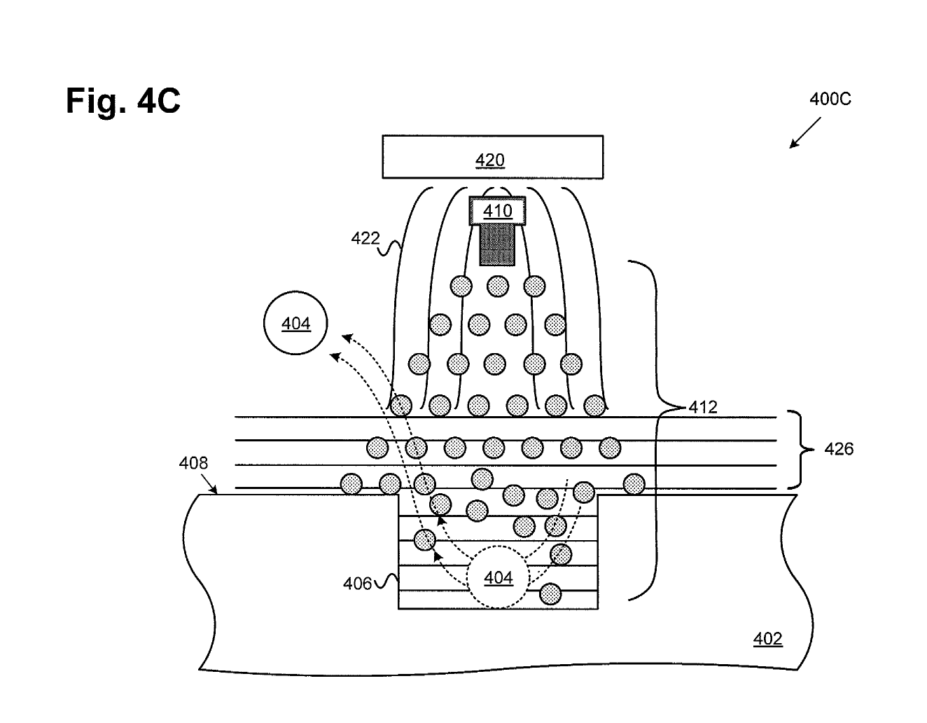

Referring to action 186 in FIG. 1 and structure 486 in FIG. 4A, action 186 includes removing the undesirable particles from the random cavities of the semiconductor package. Referring to FIG. 4A, structure 486 illustrates a schematic view of exemplary structures in accordance with action 186 in flowchart 100 of FIG. 1, according to one implementation of the present application. As illustrated in FIG. 4A, with similar numerals representing similar features in FIG. 3A, structure 486 includes semiconductor package 450 in vacuum 460, and exhaust system 424 connected to vacuum 460. As illustrated in FIG. 4A, structure 486 also includes dry ice dispenser 410 dispensing dry ice 412 into random cavity 406 of semiconductor package 450, and undesirable particle 404 being removed from random cavity 406 in semiconductor package 450 through exhaust system 424.

As shown in magnified view 400A of FIG. 4A, undesirable particle 404 is removed from random cavity 406 on semiconductor die 402 within case 452 of semiconductor package 450. Dry ice 412 sublimates into gas substantially upon impact, transferring kinetic energy to undesirable particle 404. Thus, dry ice 412 introduced into random cavity 406 provides mechanical impact to dislodge undesirable particle 404 out of random cavity 406. Undesirable particle 404 subsequently exists vacuum 460 through exhaust system 424. Also, although not explicitly shown in FIG. 4A, dry ice 412 sublimates into gas substantially upon impact (i.e., bums to gas form), and exists vacuum 460 through exhaust system 424, thus leaving no residue in random cavity 406 of semiconductor die 402.

Referring to structure 400B in FIG. 4B, structure 400B illustrates magnified view 400A in structure 486 in FIG. 4A. As illustrated in FIG. 4B, the kinetic energy transferred to undesirable particle 404 from dry ice 412 upon impact causes undesirable particle 404 to become detached and dislodged from the interior space of random cavity 406. Thus, dry ice 412 provides mechanical means to knock undesirable particle 404 out of random cavity 406 so that undesirable particle 404 can be removed from semiconductor die 402 of semiconductor package 450 through exhaust system 424.

Referring to actions 182, 184 and 186 in FIG. 1 and structure 400C in FIG. 4C, structure 400C illustrates a schematic view of exemplary structures in accordance with actions 182, 184 and 186 in flowchart 100 of FIG. 1, according to one implementation of the present application. As illustrated in FIG. 4C, with similar numerals representing similar features in FIG. 4B, structure 400C includes dry ice dispenser 410 dispensing dry ice 412 into random cavity 406 in semiconductor die 402. Structure 400C also includes nitrogen dispenser 420 dispensing compressed nitrogen 422 into random cavity 406 in semiconductor die 402.

As discussed above, nitrogen dispenser 420 delivers compressed nitrogen 422 to top surface 408 of semiconductor die 402 and the interior space of random cavity 406. While compressed nitrogen 422 can remove large particles (e.g., with diameters of 500 microns or greater), compressed nitrogen 422 creates high pressure boundary layer 426 over top surface 408, which in absence of dry ice 412 would press undesirable particle 404 (e.g., with a diameter of 25 microns or less) to the bottom of random cavity 406. However, the introduction of dry ice 412 in addition to compressed nitrogen 422 can provide mechanical means for removing undesirable particle 404 from random cavity 406.

The kinetic energy transferred to undesirable particle 404 from dry ice 412 upon impact causes undesirable particle 404 to become detached and dislodged from the interior space of random cavity 406. Thus, dry ice 412 provides mechanical means to knock undesirable particle 404 out of random cavity 406 so that undesirable particle 404 can be removed from semiconductor die 402 of semiconductor package 450 through exhaust system 424 (as illustrated in FIG. 4A). Also, although not explicitly shown in FIG. 4C, dry ice 412 sublimates substantially upon impact (i.e., burns to gas form), and exists vacuum 460 through exhaust system 424, thus leaving no residue in semiconductor package 450. After undesirable particles, such as contaminants or foreign object debris (FOD) are removed from semiconductor package 450 using dry ice 412, the random cavities and surfaces of semiconductor die 402 and/or other circuit components on substrate 454 are left clean, dry and undamaged.

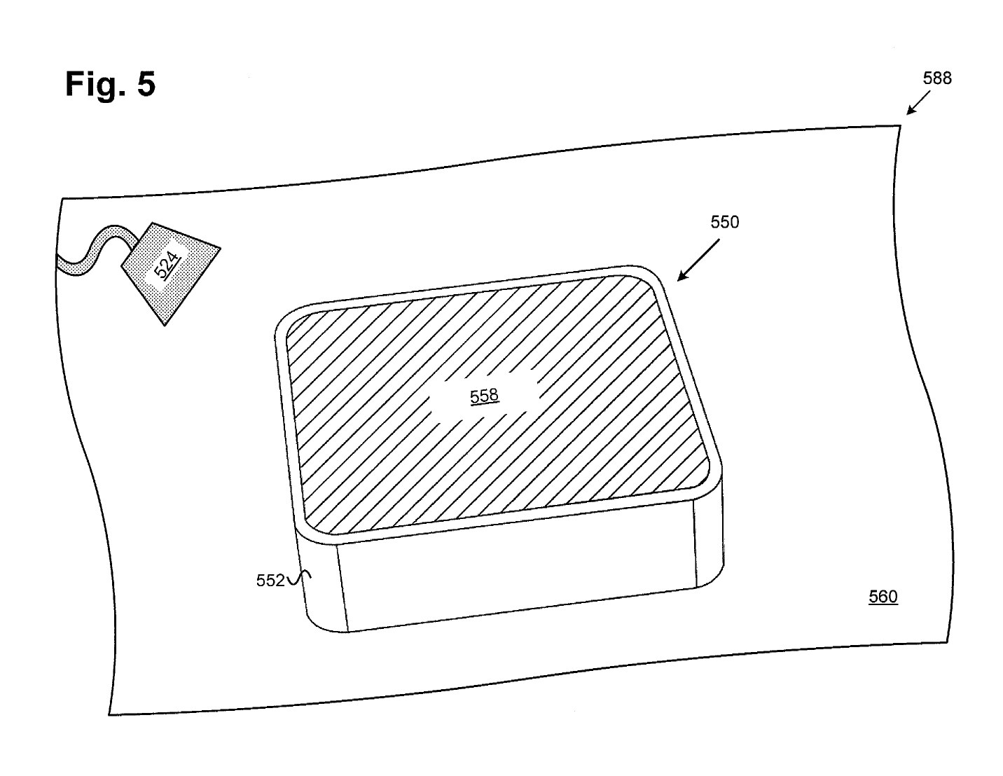

Referring to action 188 in FIG. 1 and structure 588 in FIG. 5, action 188 includes hermetically sealing the semiconductor package. Referring to FIG. 5, structure 588 illustrates a schematic view of exemplary structures in accordance with action 188 in flowchart 100 of FIG. 1, according to one implementation of the present application. As shown in FIG. 5, structure 588 includes semiconductor package 550 having hermetic lid 558 sealing semiconductor package 550. For completeness, vacuum 560 and exhaust system 524 are also shown in FIG. 5. In one implementation, hermetic lid 558 may be laser welded to case 552 to hermetically seal the packaged assembly (e.g., substrate 454 having semiconductor die 402 and other circuit components thereon) in hermetic semiconductor package 550. In other implementations, hermetic semiconductor package 550 may be hermetically sealed using any other suitable method known in the art. Also, an encapsulating molding compound or gap filler may be injected into hermetic semiconductor package 550 before it is sealed by hermetic lid 558. Thus, among other advantages, the dry ice method, according to the present implementation, allows hermetic semiconductor package 550 to be substantially free of undesirable particles. It should be noted that, in one implementation, sealing hermetic semiconductor package 550 may be optional.

From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described herein, but many rearrangements, modifications, and substitutions are possible without departing from the scope of the present disclosure.

1. A method for removing undesirable particles from a semiconductor package, said method comprising:
dispensing dry ice into random cavities of said semiconductor package;
removing said undesirable particles from said random cavities using said dry ice.

2. The method of claim 1, further comprising hermetically sealing said semiconductor package so as to produce a hermetic semiconductor package.

3. The method of claim 1, wherein said dry ice causes said undesirable particles to dislodge from said random cavities.

4. The method of claim 1, further comprising dispensing nitrogen into said random cavities.

5. The method of claim 1, further comprising placing said semiconductor package into a vacuum.

6. The method of claim 1, where at least one of said undesirable particles has a diameter approximately equal to or less than 25 microns.

7. The method of claim 1, wherein said undesirable particles are removed through an exhaust system.

8. The method of claim 1, wherein said dry ice sublimates into gas without leaving residues in said semiconductor package.

9. The method of claim 1, wherein at least one of said random cavities is on a surface of a semiconductor die in said semiconductor package.

10. The method of claim 9, wherein said semiconductor die comprises a group IV material.

11. The method of claim 9, wherein said semiconductor die comprises a group III-V material.

12. A method for cleaning a semiconductor package, said method comprising:
dispensing dry ice and nitrogen concurrently into random cavities of said semiconductor package;
removing said undesirable particles from said random cavities using said dry ice;
hermetically sealing said semiconductor package.

13. The method of claim 12, wherein said dry ice causes said undesirable particles to dislodge from said random cavities.

14. The method of claim 12, further comprising placing said semiconductor package into a vacuum.

15. The method of claim 12, where at least one of said undesirable particles has a diameter approximately equal to or less than 25 microns.

16. The method of claim 12, wherein said undesirable particles are removed through an exhaust system.

17. The method of claim 12, wherein said dry ice sublimates into gas without leaving residues in said semiconductor package.

18. The method of claim 12, wherein at least one of said random cavities is on a surface of a semiconductor die in said semiconductor package.

19. The method of claim 18, wherein said semiconductor die comprises a group IV material.

20. The method of claim 18, wherein said semiconductor die comprises a group III-V material.
